(19) United States
(12) Patent Application Publication
(10) Pub. No.: US 2022/0197345 A1
(43) Pub. Date: Jun. 23, 2022

(54) SERVICE DOORS WITH LEAF SPRING FASTENERS

(71) Applicant: Hewlett-Packard Development Company, L.P., Spring, TX (US)

(72) Inventors: Po Feng Chuang, Taipei City (TW); Wen Chih Chen, Taipei City (TW); Jian Ming Chen, Taipei City (TW)

(73) Assignee: Hewlett-Packard Development Company, L.P., Spring, TX (US)

(21) Appl. No.: 17/606,098

(22) PCT Filed: Jul. 26, 2019
(86) PCT No.: PCT/US2019/043615

§ 371 Date: Oct. 25, 2021

(51) Int. Cl. G06F 1/16; G06F 1/18

(52) U.S. Cl. CPC G06F 1/1658; G06F 1/187

(57) ABSTRACT

In one example, a device includes a service door with a leaf spring fastener. The device also includes a base of the device including a hook. The hook is disposed in the base such that the hook is to engage the leaf spring fastener in response to the leaf spring fastener being compressed via a screw being tightened on the service door to the base.

### BACKGROUND

Service doors are used to access replaceable parts in computing devices such as laptops. For example, the replaceable parts may be memory, such as random access memory, hard drives, or subscriber identification module (SIM) cards.

### BRIEF DESCRIPTION OF THE DRAWINGS

Various features of the techniques of the present application will become apparent from the following description of examples, given by way of example only, which is made with reference to the accompanying drawings, of which:

FIG. 1 is a schematic diagram showing a cross section of an example system with a service door fastened using a leaf spring fastener;

FIG. 2 is a schematic diagram of an example system with a service door having a leaf spring fastener with a screw removed;

FIG. 3 is a schematic diagram of an example leaf spring fastener engaging a hook in a base of a device;

FIG. 4 is a schematic diagram of an example leaf spring fastener being detached from a hook in a base of a device as a screw is removed;

FIG. 5 is a schematic diagram of the bottom of an example system with a service door attached according to techniques described herein;

FIG. 6 is a process flow diagram illustrating an example method for removing a service door with a leaf spring fastener from a base of a device;

FIG. 7 is a process flow diagram illustrating an example method for fastening a service door with a leaf spring fastener to a base of a device; and

FIG. 8 is a process flow diagram illustrating an example method for manufacturing a device with a service door having a leaf spring fastener.

### DETAILED DESCRIPTION

Computing devices may include service doors to enable easy access to parts for replacement of failed or older parts. However, such service doors may accidentally open in some situations. For example, service doors may accidentally open when a computing device is dropped or experiences another sudden force. Moreover, manually sliding fasteners that are pushed into position to lock the service door by hand may be overlooked and thus not able to provide additional support.

Described herein are techniques for manufacturing a service door with a leaf spring fastener. As used herein, a leaf spring fastener refers to a leaf spring that fastens a service door to a base of a computing device. In some examples, the leaf spring may also provide force against a screw. For example, the leaf spring fastener may be disposed in the service door such that the leaf spring fastener engages a hook in the base of a computing device when a screw is tightened. In some examples, the screw may be tightened through or next to the leaf spring fastener. In some examples, the leaf spring fastener may include a hook to engage the hook of the base of the computing device. In addition, any number of leaf spring fasteners may be included in the service door. The techniques described herein thus enable a service door to be more securely fastened, preventing or reducing the occurrence of accidental removals of the service door. In addition, the techniques described herein enable the service door to be easily removed by pushing the service door away from the base as a screw is untightened.

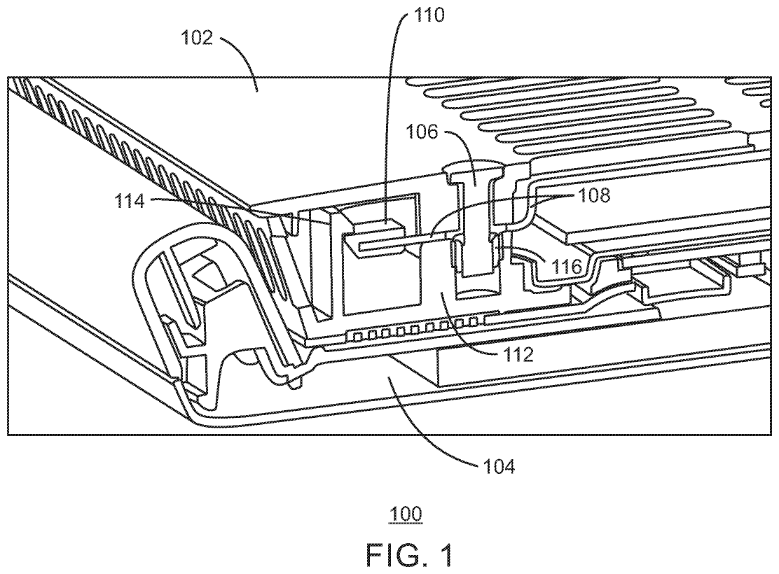

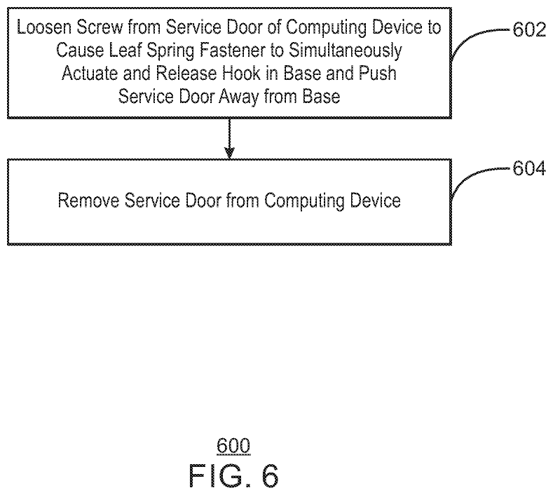

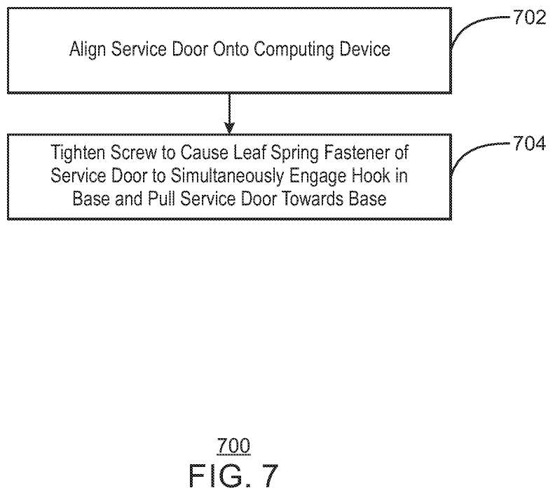

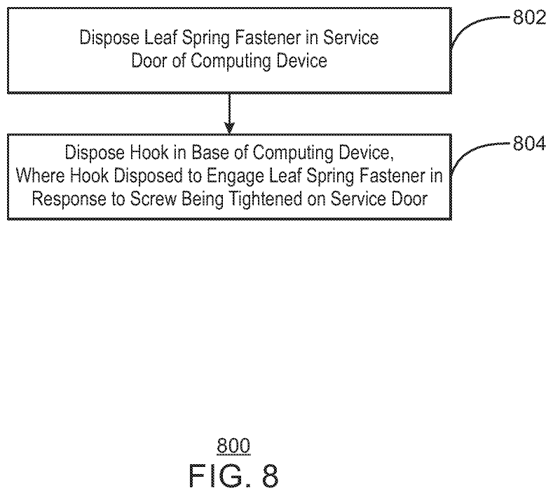

FIG. 1 is a block diagram showing a cross section of an example system with a service door fastened using a leaf spring fastener. The example system 100 can be manufactured using method 800 of FIG. 8 and may operate using the methods 600 and 700 of FIGS. 6 and 7. In various examples, the system 100 may be a mobile computing device, such as a laptop or a smart phone.

The system 100 includes a service door 102 that is mechanically coupled to a base 104 of the system 100. The system 100 further includes a screw 106 that is tightened to hold the service door 102 against the base 104. The system 100 includes a leaf spring fastener 108 coupled to the service door 102. For example, the leaf spring fastener may be welded, glued, or otherwise coupled to the service door 102 using any suitable technique. The leaf spring fastener 108 includes a hook 110 coupled to leaf spring fastener 108. For example, the hook 110 may be glued onto the end of the leaf spring fastener 108, or attached to one end of the leaf spring fastener 108 using any other suitable technique. The leaf spring fastener 108 of FIG. 1 includes a hole through which the screw 106 is to be received at the base 104. The system 100 also further includes a top cover rib 112 in the base 104 of the system 100. The top cover rib 112 is engaged with the leaf spring fastener 108 to compress the leaf spring fastener 108 against the service door 102. The system 100 also further includes a hook 114 coupled to the base 104. For example, the hook 114 may be molded as part of the base 104. The hook 114 may be disposed in the base 104 such that the hook 114 is to engage the leaf spring fastener 108 in response to the leaf spring fastener 108 being compressed via the screw 106 being tightened on the service door 102 to the base 104. The hook 114 is shown further coupled to the hook 110 of the leaf spring fastener 108 via the compression force in the leaf spring fastener 108. In addition, the screw 106 is shown being tightened to a screw receiver 116. For example, the screw receiver 116 may be a nut. The nut may be a piece of material having a cylindrical hole, with a helical groove cut around the inside of the hole. In some examples, the screw receiver 116 may be a cylindrical hole cut directly into a surface of the base 104.

In the example system 100, the leaf spring fastener 108 may provide additional fastening support to the service door 102 in addition to providing force against the screw 106. For example, the service door 102 may be held by both the screw 106 that is coupled to the base 104 via a screw receiver as well as by the hook 110 of the leaf spring fastener 108 pressing against the hook 114 of the base 104. For example, the hook 110 may be displaced towards the hook 114 of the base 104 as the leaf spring fastener 108 is compressed. In this manner, the service door 102 is less likely to accidentally be released from the base 104 upon being dropped or otherwise exposed to sudden external forces.

The block diagram of FIG. 1 is not intended to indicate that the example system 100 is to include all of the components shown in FIG. 1. Further, the system 100 may include any number of additional components not shown in FIG. 1, depending on the details of the specific implementation. In various examples, the system 100 may include additional leaf spring fasteners, screws, hooks, top cover ribs, and etc. For example, the system 100 may include a number of hooks 114 in the base 104 to engage the leaf spring fastener 108. For example, the hooks 114 may be aligned horizontally on two sides of the screw receiver 116 in the base 104 of the device.

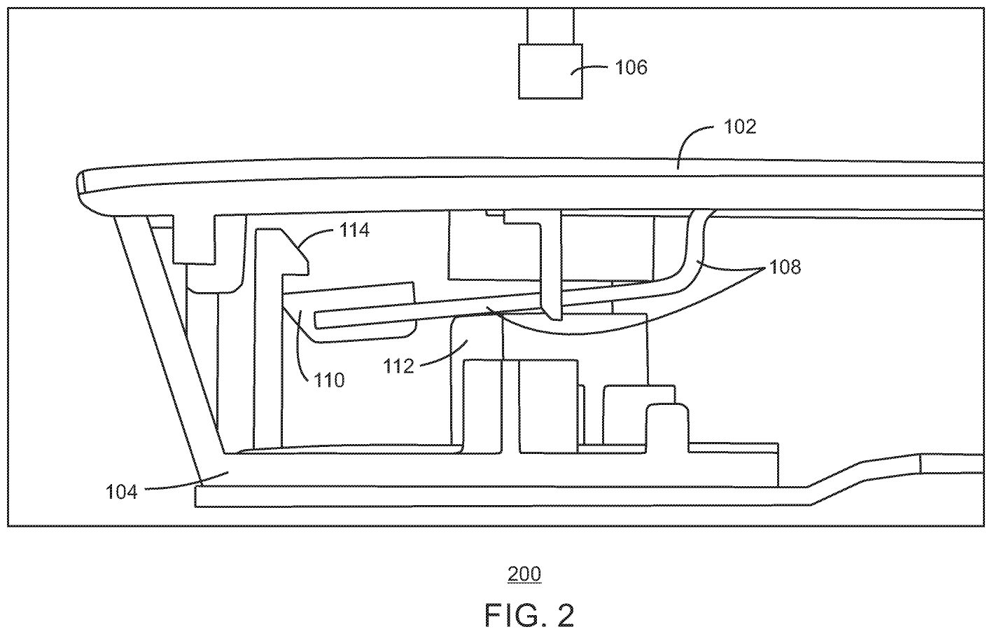

FIG. 2 is a schematic diagram of an example system with a service door having a leaf spring fastener with a screw removed. The system 200 includes similarly numbered elements of FIG. 1 and can be manufactured using method 800 of FIG. 8 and can operate using the methods 600 and 700 of FIGS. 6 and 7. In various examples, the system 200 may be a mobile computing device, such as a laptop or a smart phone.

In the system 200 of FIG. 2, the screw 106 is shown above and removed from the base 104 and is thus not holding the service door 102 to the base 104. The leaf spring fastener 108 is shown in an uncompressed state and has forced the service door 102 away from the base 104 by pushing against the top cover rib 112. For example, the top cover rib 112 may be disposed in the base 104 to compress the leaf spring fastener 108 against the service door 102 in response to the screw 106 being tightened at the service door 102 into a screw receiver of the base 104. Moreover, the hook 110 of the leaf spring fastener 108 is not engaged with the hook 114 of the base 104. Thus, in addition to providing further support to the screw 106 in securing the service door 102 to the base 104 when the screw is installed and tightened, the leaf spring fastener 108 may also provide force against the service door 102 to enable the service door 102 to be more easily released from the base 104.

The block diagram of FIG. 2 is not intended to indicate that the example system 200 is to include all of the components shown in FIG. 2. Further, the system 200 may include any number of additional components not shown in FIG. 2, depending on the details of the specific implementation. For example, the system 200 may include additional leaf spring fasteners, screws, hooks, top cover ribs, and etc.

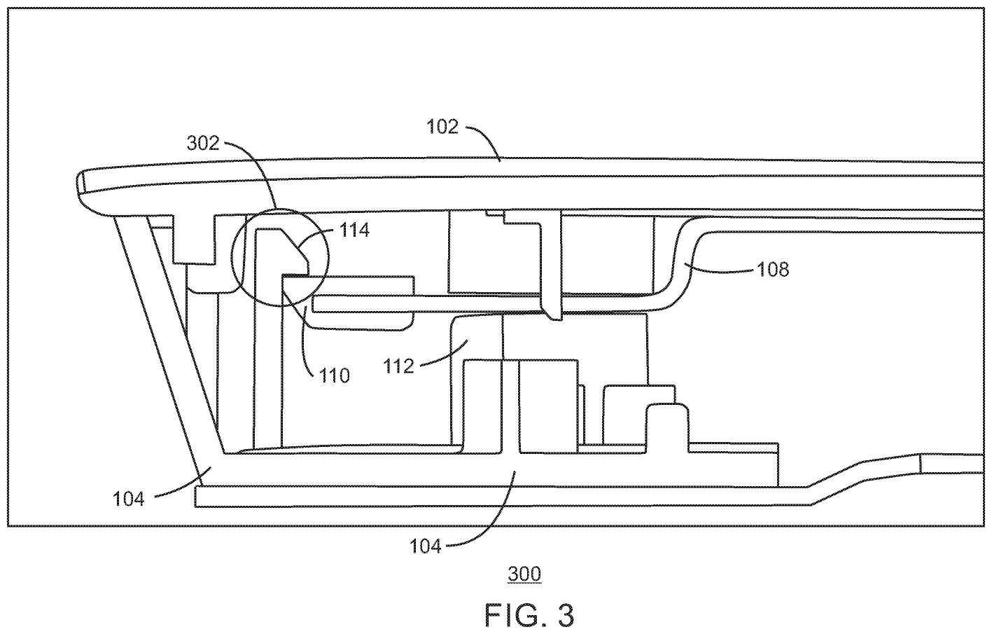

FIG. 3 is a schematic diagram of an example leaf spring fastener engaging a hook in a base of a device. The system 300 includes similarly numbered elements of FIG. 1 can be manufactured using method 800 of FIG. 8 and can operate using the methods 600 and 700 of FIGS. 6 and 7. In various examples, the system 300 may be a mobile computing device, such as a laptop or a smart phone.

In the system 300 of FIG. 3, the screw (not shown) is inside the screw receiver and holding the service door 102 to the base 104. For example, the screw may be located near the top cover rib, or may be located outside of FIG. 3. The leaf spring fastener 108 is being pressed by the top cover rib 112 causing the hook 110 of the leaf spring fastener 108 to press against and thus engage the hook 114 of the base 104, as highlighted by circle 302. In this manner, the leaf spring fastener 108 provides additional fastening strength to hold the service door 102 to the base 104. Thus, if the system 300 is dropped or experiences any other form of sudden forces, the leaf spring fastener 108 may provide additional fastening support to prevent the service door 102 from accidentally being released from the base 104.

The block diagram of FIG. 3 is not intended to indicate that the example system 300 is to include all of the components shown in FIG. 3. Further, the system 300 may include any number of additional components not shown in FIG. 3, depending on the details of the specific implementation. In various examples, the system 300 may include additional leaf spring fasteners, screws, hooks, top cover ribs, and etc. For example, the base 104 may include a number of hooks 114 to engage a number of hooks 110 of the leaf spring fastener 108. In some examples, the base 104 may include a number of hooks 114 to engage a number of hooks 110 of a number of leaf spring fasteners 108.

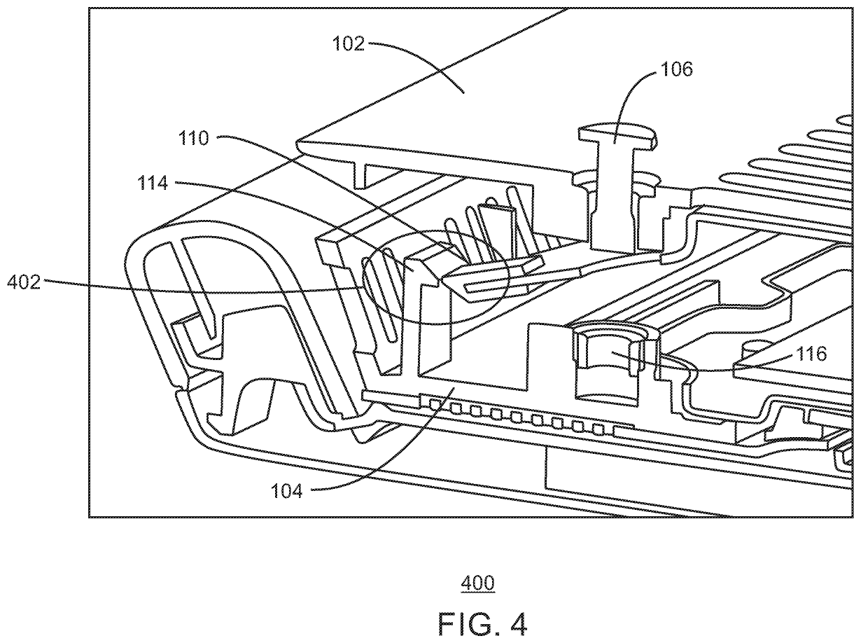

FIG. 4 is a schematic diagram of an example leaf spring fastener being detached from a hook in a base of a device as a screw is removed. The system 400 includes similarly numbered elements of FIG. 1 can be manufactured using method 800 of FIG. 8 and can operate using the methods 600 and 700 of FIGS. 6 and 7. In various examples, the system 400 may be a mobile computing device, such as a laptop or a smart phone.

In the system 400 of FIG. 4, the screw 106 is being removed from the screw receiver. As shown in oval 402, the leaf spring fastener 108 may disengage the hook 114 while simultaneously pushing the service door 102 away from the base 104 in response to the screw 106 being loosened. The service door 102 may then be more easily removed from the base 104. For example, no additional sliders or mechanisms may need to be activated prior to removing the service door 102 from the base 104.

The block diagram of FIG. 4 is not intended to indicate that the example system 400 is to include all of the components shown in FIG. 4. Further, the system 400 may include any number of additional components not shown in FIG. 4, depending on the details of the specific implementation. For example, the system 400 may include additional leaf spring fasteners, screws, hooks, top cover ribs, and etc.

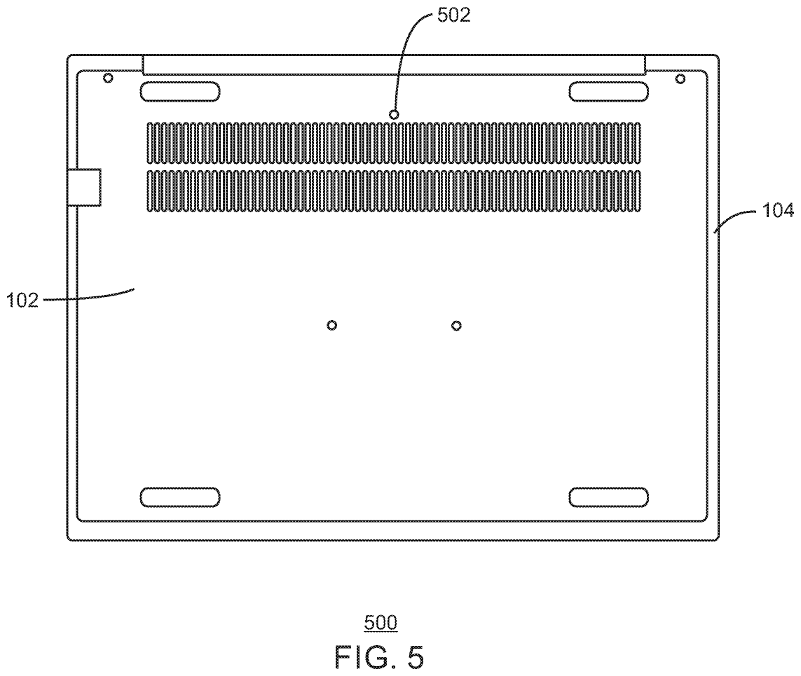

FIG. 5 is a schematic diagram of the bottom of an example system with a service door attached according to techniques described herein. The system 500 includes similarly numbered elements of FIG. 1 can be manufactured using method 800 of FIG. 8 and can operate using the methods 600 and 700 of FIGS. 6 and 7. In various examples, the system 500 may be a mobile computing device, such as a laptop or a smart phone.

The system 500 of FIG. 5 shows a service door 102 with a hole 502 to receive a screw. In various examples, a leaf spring fastener located at the hole 502 may be compressed upon a screw being received and tightened at a screw receiver behind the hole 502. In some examples, a number of hooks may be disposed in the base 104 on either side of the hole 502 to engage the leaf spring fastener in response to the screw being tightened. For example, the screw may cause the leaf spring fastener of the service door 102 to push against a top cover rib of the base 104. The top cover rib may thus cause the a hook or hooks of the leaf spring fastener to engage a hook or hooks of the base 104 as described herein. In some examples, the hole 502 and the leaf spring fasteners and the hooks may not necessarily be horizontally aligned with each other.

The block diagram of FIG. 5 is not intended to indicate that the example system 500 is to include all of the components shown in FIG. 5. Further, the system 500 may include any number of additional components not shown in FIG. 5, depending on the details of the specific implementation. For example, the system 500 may include additional leaf spring fasteners, screws, hooks, top cover ribs, and etc.

FIG. 6 is a process flow diagram illustrating an example method for removing a service door with a leaf spring fastener from a base of a device. The method 600 of FIG. 6 can be implemented using the service door described in FIGS. 1-5.

At block 602, a screw is loosened from the service door of a computing device to cause the leaf spring fastener to simultaneously actuate and release a hook in the base and push the service door away from the base. In some examples, the leaf spring fastener may simultaneously release a number of hooks in the base and push the service door away from the base. In some examples, a number of leaf spring fasteners may be simultaneously actuated and release hooks in the base and push the service door away from the base.

At block 604, the service door is removed from the computing device. For example, the service door may be separated from the base of the computing device to access one or more components inside the base of the computing device. In various examples, one or more components may be replaced and the service door closed again using the method 700 of FIG. 7.

It is to be understood that the process diagram of FIG. 6 is not intended to indicate that all of the elements of the method 600 are to be included in every case. Further, any number of additional elements not shown in FIG. 6 may be included in the method 600, depending on the details of the specific implementation.

FIG. 7 is a process flow diagram illustrating an example method for fastening a service door with a leaf spring fastener to a base of a device. The method 600 of FIG. 6 can be implemented using the service door described in FIGS. 1-5.

At block 702, a service door is aligned onto a computing device. For example, the service door may be aligned mechanically using one or more alignment tabs or grooves in the base of the computing device. In various examples, a locating pin may be used with a locating hole to align the service door with the base of the computing device. In some examples, the service door may be aligned magnetically using one or more magnets.

At block 704, a screw is tightened to cause a leaf spring fastener of the service door to simultaneously engage a hook in the base and pull the service door towards the base. For example, the base of the computing device may include a hook that is positioned to receive a hook of the leaf spring fastener in response to the leaf spring fastener being compressed by the tightening of the screw. In some examples, the base may include a number of hooks positioned to receive a number of hooks of the leaf spring fastener. For example, the leaf spring fastener may include a hook on two leafs that project in opposing directions. In various examples, the base may include a number of hooks positioned to simultaneously receive a number of hooks from any number of leaf spring fasteners.

It is to be understood that the process diagram of FIG. 7 is not intended to indicate that all of the elements of the method 700 are to be included in every case. Further, any number of additional elements not shown in FIG. 7 may be included in the method 700, depending on the details of the specific implementation.

FIG. 8 is a process flow diagram illustrating an example method for manufacturing a device with a service door having a leaf spring fastener. The method 800 of FIG. 8 can be implemented to manufacture the service door of FIGS. 1-5.

At block 802, a leaf spring fastener is disposed in a service door of a computing device. For example, the leaf spring fastener is disposed to simultaneously generate a release force in response to the screw being tightened on the service door. In some examples, the leaf spring fastener is disposed to cause the service door to be pushed away from the base of the computing device in response to the screw being unscrewed from the service door. In various examples, the leaf spring fastener is disposed to engage and be compressed by a top cover rib in the base of the computing device.

At block 804, a hook is disposed in a base of the computing device. The hook is disposed to engage the leaf spring fastener in response to a screw being tightened on the service door. In some examples, a second hook is disposed in the leaf spring fastener to engage the hook of in the base of the computing device. In various examples, a number of hooks are disposed in the base of the computing device to engage the leaf spring fastener in the service door next to a screw receiver of the service door.

It is to be understood that the process diagram of FIG. 8 is not intended to indicate that all of the elements of the method 800 are to be included in every case. Further, any number of additional elements not shown in FIG. 8 may be included in the method 800, depending on the details of the specific implementation. For example, the method 800 may include disposing a number of hooks comprising the hook in the base of the computing device to engage the leaf spring fastener in response to the screw being tightened and to disengage the leaf spring fastener in response to the screw being loosened. In various examples, a number of hooks may be disposed in the base of the computing device to engage a number of leaf spring fasteners disposed in the service door.

While the present techniques may be susceptible to various modifications and alternative forms, the examples discussed above have been shown only by way of example. It is to be understood that the technique is not intended to be limited to the particular examples disclosed herein. Indeed, the present techniques include all alternatives, modifications, and equivalents falling within the true spirit and scope of the appended claims.

What is claimed is:

1. A device, comprising:
a service door with a leaf spring fastener; and
a base of the device comprising a hook, the hook disposed in the base such that the hook is to engage the leaf spring fastener in response to the leaf spring fastener being compressed via a screw being tightened on the service door to the base.

2. The device of claim 1, wherein the leaf spring fastener comprises a second hook to engage the hook in the base, the second hook to be displaced towards the hook of the base as the leaf spring fastener is compressed.

4. The device of claim 1, wherein the leaf spring fastener is to disengage the hook and push the service door away from the base in response to the screw being loosened.

5. The device of claim 1, wherein a plurality of hooks in the base to engage the leaf spring fastener are aligned horizontally on two sides of a screw receiver in the base.

6. The device of claim 1, comprising a top cover rib in the base to compress the leaf spring fastener against the service door in response to the screw being tightened at the service door into a screw receiver of the base.

6. A method comprising:
disposing a leaf spring fastener in a service door of a computing device; and
disposing a hook in a base of the computing device, the hook disposed to engage the leaf spring fastener in response to a screw being tightened on the service door.

7. The method of claim 6, comprising disposing a second hook in the leaf spring fastener to engage the hook of in the base of the computing device.

8. The method of claim 6, wherein the leaf spring fastener is disposed to further simultaneously generate a release force in response to the screw being tightened on the service door.

9. The method of claim 6, wherein the leaf spring fastener is disposed to cause the service door to be pushed away from the base of the computing device in response to the screw being unscrewed from the service door.

10. The method of claim 6, comprising disposing a plurality of hooks comprising the hook in the base of the computing device to engage the leaf spring fastener in response to the screw being tightened and to disengage the leaf spring fastener in response to the screw being loosened.

11. An apparatus, comprising:
a service door with a leaf spring fastener;
a base of the device comprising a hook, the hook disposed in the base such that the hook is to engage the leaf spring fastener in response to the leaf spring fastener being compressed via a screw being tightened on the service door to the base; and
a top cover rib in the base to compress the leaf spring fastener against the service door in response to the screw being tightened at the service door into a screw receiver of the base

12. The apparatus of claim 11, wherein the leaf spring fastener comprises a second hook to engage the hook in the base, the second hook to be displaced towards the hook of the base as the leaf spring fastener is compressed.

13. The apparatus of claim 11, wherein the leaf spring fastener comprises a hole through which the screw is to be received at the base

14. The apparatus of claim 11, wherein the leaf spring fastener is to disengage the hook and push the service door away from the base in response to the screw being loosened.

15. The apparatus of claim 11, wherein a plurality of hooks in the base to engage the leaf spring fastener are aligned horizontally on two sides of a screw receiver in the base.
